(19) United States
(12) Patent Application Publication
(10) Pub. No.: US 2010/0156462 A1
(43) Pub. Date: Jun. 24, 2010

(54) PROGRAMMABLE LOGIC ARRAY AND PROGRAMMABLE LOGIC ARRAY MODULE GENERATOR

(76) Inventor: Akihito Katsura, Osaka (JP)

Correspondence Address: MCDERMOTT WILL & EMERY LLP, 600 13TH STREET, NW, WASHINGTON, DC, 20005-3096, US

(21) Appl. No.: 11/997,644

(22) PCT Filed: Aug. 1, 2006
(86) PCT No.: PCT/JP2006/315196

§ 371 Date: Feb. 1, 2008

(30) Foreign Application Priority Data
Aug. 1, 2005 (JP) 2005-223045

(51) Int. Cl. H03K 19/177

(52) U.S. Cl. 326/44; 326/39

(57) ABSTRACT

A PLA contains an input plane (10) including a plurality of data lines (103) and a plurality of product term lines (104) having voltage levels changed in accordance with signal input to the plurality of data lines; and an output plane (20) including a plurality of product term lines (204) having voltage levels changed in accordance with the change of the voltage levels of the plurality of product term lines of the input plane and a plurality of data lines (203) for outputting signals in accordance with the voltage levels of the plurality of product term lines. In this PLA, at least one of the data lines of at least one of the input plane and the output plane has data terminals (101) at both ends thereof.

### TECHNICAL FIELD

The present invention relates to a programmable logic array and a programmable logic array module generator, and more particularly, it relates to a programmable logic array in which spurious radiation (EMI) is reduced.

### BACKGROUND ART

As a conventional programmable logic array (hereinafter sometimes abbreviated to the “PLA”), one including a CMOS and one including a dynamic circuit are known (see, for example, Non-patent Document 1). Also, with respect to the architecture of a PLA, a technique for reducing the chip area while improving the yield is known (see, for example, Patent Document 1).

Patent Document 1: Japanese Patent Application No. 59-238921

Non-patent Document 1: Takashi Tomizawa and Yasuo Matsuyama, “Principle of CMOS VLSI design”, Maruzen Co. Ltd., pp. 326-335)

### DISCLOSURE OF THE INVENTION

### Problems to be Solved by the Invention

Recently, in accordance with the increased speed of a system LSI, EMI (electro magnetic interference) has been regarded as a serious problem. In a conventional architecture of a dynamic PLA, however, data are output at the same timing and input/output terminals are disposed to be aligned in one direction, and therefore, portions where peak currents are generated are collected. Furthermore, since the directions of currents are the same, generated magnetic fields are superimposed, and hence, functional blocks and chips disposed around the PLA suffer from large spurious radiation (EMI). Moreover, the influence of the EMI is found after completing a chip in many cases, and when a mask is modified every time the influence is found, enormous development cost and labors are necessary.

In addition, in the case where input terminals and output terminals are disposed on the same side in an unbalanced manner, it is apprehended that excessive overhead may be caused in an interconnection layout in a region between the PLA and a previous or subsequent functional block.

Also, in the conventional PLA, owing to its architecture, a steady state current flows when power is supplied. For example, when an array transistor is in an on state in an input plane or an output plane, a current continuously flows from a power supply through the transistor to the ground. Accordingly, even in a state where the power is supplied but an effective output is not taken out because the PLA is not used (hereinafter sometimes referred to as an “unused state”), a steady state current unavoidably flows. Such a steady state current flowing in an unused state is wasteful and increases the power consumption. Furthermore, such a steady state current increases as the scale of the PLA is increased and as the number of transistors present in a plane for programming is increased, and therefore, the increase of the power consumption caused in an unused state is a significant problem. At the same time, even when the PLA is placed in an unused state for a long period of time, the power consumption is increased.

### Means for Solving the Problems

In order to solve the aforementioned problems, the invention provides a programmable logic array containing an input plane including a plurality of data lines and a plurality of product term lines having voltage levels changed in accordance with signal input to the plurality of data lines; and an output plane including a plurality of product term lines having voltage levels changed in accordance with change of the voltage levels of the plurality of product term lines of the input plane and a plurality of data lines for outputting signals in accordance with the voltage levels of the plurality of product term lines, in which at least one of the plurality of data lines of at least one of the input plane and the output plane has data terminals at both ends thereof.

Also, the invention provides a programmable logic array module generator including a file reading section for reading a logic description file related to a programmable logic array; a truth table sorting section for exchanging a plurality of data lines of at least one of an input plane and an output plane of the programmable logic array described by the logic description file in such a manner that a data line including a relatively large number of transistors is adjacent to a data line including a relatively small number of transistors; a base layout generating section for generating a base layout on the basis of a logic description file obtained by exchanging the data lines; an input plane programming section for positioning an array in the input plane on the basis of the logic description file obtained by exchanging the data lines; and an output plane programming section for positioning an array in the output plane on the basis of the logic description file obtained by exchanging the data lines.

### EFFECT OF THE INVENTION

In the programmable logic array of this invention, circuit portions where peak currents are generated in discharge are dispersed, and hence, superimposition of magnetic fields is reduced. Also, in the programmable logic array module generator of this invention, the orders of a term where a signal is easily changed and a term where a signal is minimally changed are exchanged, and hence, circuit portions where peak currents are generated are dispersed before mask layout. Thus, a programmable logic array in which the superimposition of magnetic fields is comparatively small is laid out.

### BRIEF DESCRIPTION OF DRAWINGS

FIG. 1 is a schematic diagram of a programmable logic array according to Embodiment 1.

FIG. 2 is a schematic diagram of a programmable logic array according to Embodiment 2.

FIG. 3 is a schematic diagram of a programmable logic array according to Embodiment 3.

FIG. 4 is a cross-sectional view of data lines of a programmable logic array according to Embodiment 4.

FIG. 5 is a cross-sectional view of data lines of a programmable logic array according to Embodiment 5.

FIG. 6 is a schematic diagram of an event driven interface portion of a programmable logic array according to Embodiment 6.

FIG. 7 is a truth table of an event generation memory circuit shown in FIG. 6.

FIG. 8 is a timing chart for an event driven interface shown in FIG. 6.

FIG. 9 is a schematic diagram of a programmable logic array according to Embodiment 7.

FIG. 10 is a schematic diagram of a programmable logic array module generator according to the invention.

FIG. 11 is a diagram for explaining the outline of truth table sorting.

### DESCRIPTION OF REFERENCE NUMERALS

101, 201 data terminal
105, 205 Pch transistor (precharge circuit)
102A buffer circuit
31 event generation memory circuit
32 event driven interface
322 Pch transistor (second voltage supply circuit)
323 Pch transistor (first voltage supply circuit)
326 Pch transistor (precharge circuit)
100 file reading section
200 truth table sorting section
300 base layout generating section
400 input plane programming section
500 output plane programming section

### BEST MODE FOR CARRYING OUT THE INVENTION

Preferred embodiments for practicing the invention will now be described with reference to the accompanying drawings.

### Embodiment 1

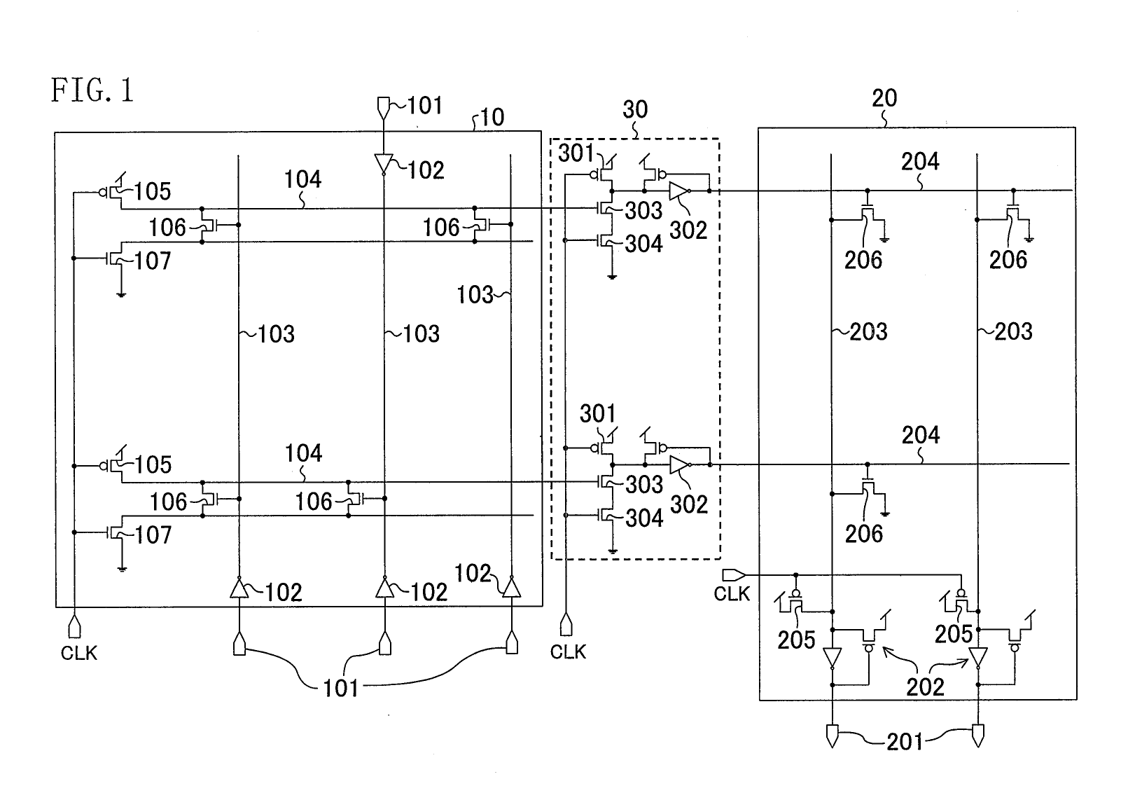

FIG. 1 shows the configuration of a PLA according to Embodiment 1 of the invention. The PLA of this embodiment includes an input plane 10 constructed as an AND array, an output plane 20 constructed as an OR array and an interface buffer 30. In the input plane 10, a reference numeral 101 denotes an input terminal, a reference numeral 102 denotes an input buffer, a reference numeral 103 denotes a data line, a reference numeral 104 denotes a product term line, a reference numeral 105 denotes a Pch transistor working as a precharge circuit, and a reference numeral 106 denotes an Nch transistor working as an array transistor. On the other hand, in the output plane 20, a reference numeral 201 denotes an output terminal, a reference numeral 202 denotes an output buffer, a reference numeral 203 denotes a data line, a reference numeral 204 denotes a product term line, a reference numeral 205 denotes a Pch transistor working as a precharge circuit and a reference numeral 206 denotes an Nch transistor working as an array transistor.

Examples of the operation content programmed in each plane are AND, OR and the like, and the input plane 10 and the output plane 20 are not uniquely defined respectively as the AND plane and the OR plane but may be reversed or may be NOR and NOR planes.

At least one of the plural data lines 103 of the input plane 10 is constructed to be able to receive input bidirectionally in the input plane 10, and the input terminals 101 are provided at the both ends of this one data line. Data are input to a plurality of input terminals 101 to be subjected to the logic operation programmed in each of the input plane 10 and the output plane 20, and results of the operation are output from a plurality of output terminals 201.

Since the PLA of this embodiment is a precharge type, precharge and evaluation are repeatedly performed in synchronization with a clock CLK in its operation roughly speaking. The logic operation is performed in the input plane 10 in the first clock cycle, data are transferred to the output plane 20 through the product term lines 104 in the second clock cycle, and the logic operation is performed in the output plane 20 for outputting data in the third clock cycle.

The operation of the PLA of FIG. 1 is as follows: First, in the input plane 10, when the clock CLK is at Lo level, a power voltage VDD is applied to a plurality of product term lines 104 of the input plane 10 by the Pch transistors 105, so as to place the product term lines 104 at Hi level. At this point, when a signal at Lo level is supplied to one of the plural input terminals 101 of the input plane 10, a data line 103 receiving the signal from this input terminal 101 is set to Hi level, and hence, an Nch transistor 106 whose gate terminal is connected to this data line 103 is turned on. In the case where the clock CLK is changed to Hi level when the Nch transistor 106 is in an on state, the product term line 104 is connected to the ground through the Nch transistor 107, and hence, the product term line 104 is set to Lo level.

Next, when a clock CLK is at Lo level in the interface buffer 30, the plural product term lines 204 of the output plane 20 are placed at Lo level by Pch transistors 301 and buffers 302. When a product term line 104 is at Lo level, an Nch transistor 303 whose gate terminal is connected to this product term line 104 is placed in an off state. Thereafter, even when the clock CLK is changed to Hi level and an Nch transistor 304 is turned on, the Nch transistor 303 is kept in an off state, and therefore, the output of the interface buffer 30 is kept at Lo level and the product term line 204 of the output plane 20 is kept at Lo level.

Next, when a clock CLK is at Lo level in the output plane 20, a power voltage VDD is applied to a plurality of data lines 203 of the output plane 20 by the Pch transistors 205, and hence the data lines 203 are set to Hi level. When a product term line 204 is at Lo level, an Nch transistor 206 whose gate terminal is connected to this product term line 204 is in an off state. The drain terminal of this Nch transistor 206 is connected to one of the plural data lines 203, and when all the Nch transistors 206 connected to this one data line 203 are in an off state, this data line 203 is kept at Hi level even if the clock CLK is changed to Lo level. As a result, the level is inverted by the output buffer 202, so as to output a signal at Lo level from the output terminal 201.

On the other hand, when a signal at Hi level is supplied to the input plane 10, the operations in the AND array and the OR array are reversed. Specifically, the product term line 104 of the input plane 10 is kept at Hi level, the output of the interface buffer 30 is kept at Hi level, the Nch transistor 206 of the output plane 20 is turned on to be connected to the ground, and hence, a signal at Hi level is output from the output terminal 201.

In the PLA of this embodiment, a signal can be input to the input plane 10 through an arbitrary input terminal 101. In order to avoid local collection of signal input, the input buffers 102 where peak currents are generated can be dispersed particularly by dispersing signal input directions to the data line 103 having the input terminals 101 at both ends thereof. Furthermore, when the input terminals 101 are provided on both sides of the input plane 10, interconnections to be connected to previous and subsequent functional blocks can be provided at minimum distances in a signal interconnection layout, resulting in increasing the degree of interconnecting freedom.

It is noted that a data line 203 of the output plane 20 may be also provided with the output terminals 201 at its both ends.

### Embodiment 2

In the PLA of Embodiment 1, it is assumed that, for example, some of the Nch transistors 106 are in an off state and the other Nch transistors 106 undergo an on-to-off transition. In this case, the product term line 104 and the drain (or source) capacitances of the Nch transistors 106 are basically all charged to Hi level (a power voltage) during a period when the clock signal CLK is at Lo level (namely, during a precharge period). Then, during a period when the clock signal CLK is at Hi level (namely, during a discharge period), a signal at Hi level is to be output from the product term line 104. However, in the case where the precharge period overlaps a level transition period of the input signal, for example, in the case where an Nch transistor 106 disposed in the vicinity of a Pch transistor 105 is turned on immediately before the end of the precharge period, the drain (or source) capacitance of the Nch transistor 106 cannot be fully charged in the remaining precharge period, and therefore, what is called charge share may be caused so that data stored on the product term line 104 may be changed from Hi level to Lo level (ground voltage). Owing to this phenomenon, a signal that should be at Hi level is output at Lo level, which can be a factor of malfunction of the PLA.

In order to avoid the aforementioned phenomenon, the parasitic capacitance of the product term line 104 such as the drain (or source) capacitance of the Pch transistor 105 may be increased so as to keep the product term line 104 at Hi level even when the charge share occurs. However, this means that the capacitance to be discharged in reading (discharging) is increased, and hence the reading speed is disadvantageously reduced. Alternatively, an auxiliary precharge transistor may be additionally provided, which is not preferred because the circuit area is thus increased. On the other hand, the transition of an address (the level transition of an input signal) may be completed sufficiently earlier than the end of the precharge period so as to sufficiently perform necessary precharge, but this increases the load of set-up time of the address and there arises a problem that time otherwise available for the operation or the like should be wasted.

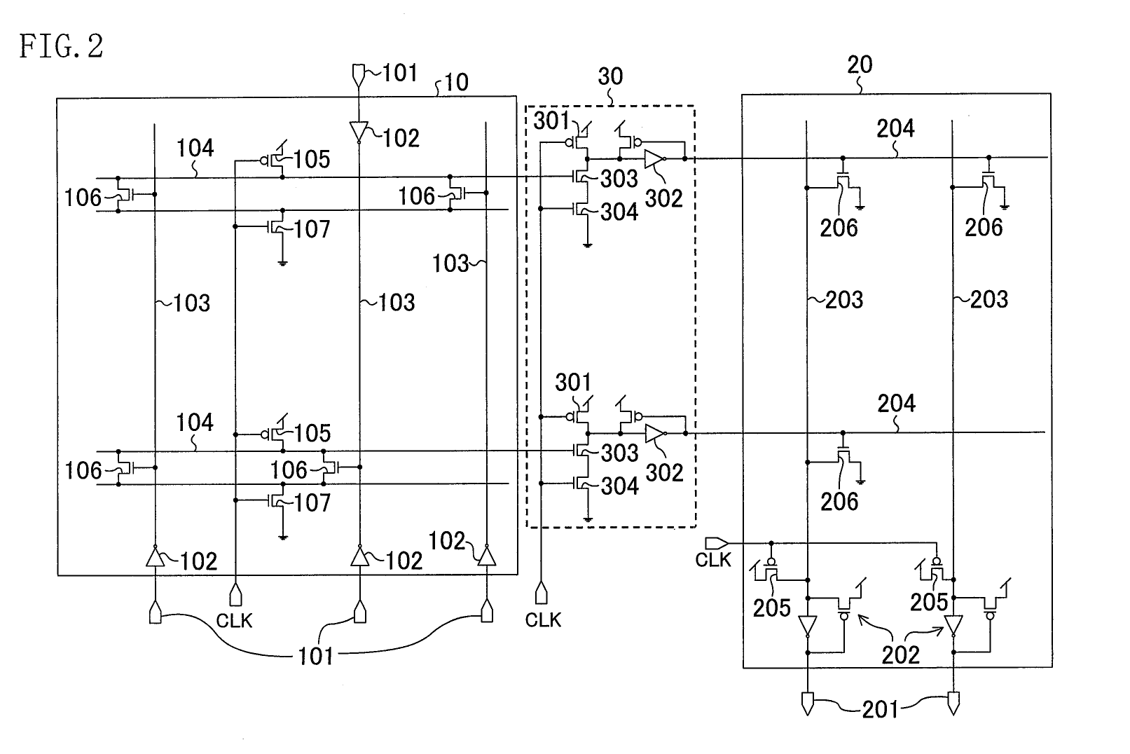

Therefore, in Embodiment 2 of the invention, a PLA in which the aforementioned problem is solved is provided. FIG. 2 shows the configuration of the PLA of this embodiment. In the PLA of this embodiment, the precharge circuit (the Pch transistor 105) of the input plane 10 of the PLA of FIG. 1 is provided at the center along the length direction of the product term line 104. The rest of the configuration is the same as that of Embodiment 1 and hence the description is omitted.

Since the precharge circuit is thus provided at the center of the product term line 104, precharge time necessary per length of the product term line 104 is shortened and an even precharge potential level is supplied. Therefore, the occurrence of the charge share is reduced.

It is noted that the precharge circuit (the Pch transistor 205) of the output plane 20 may be provided at the center along the length direction of the data line 203 of the output plane 20.

### Embodiment 3

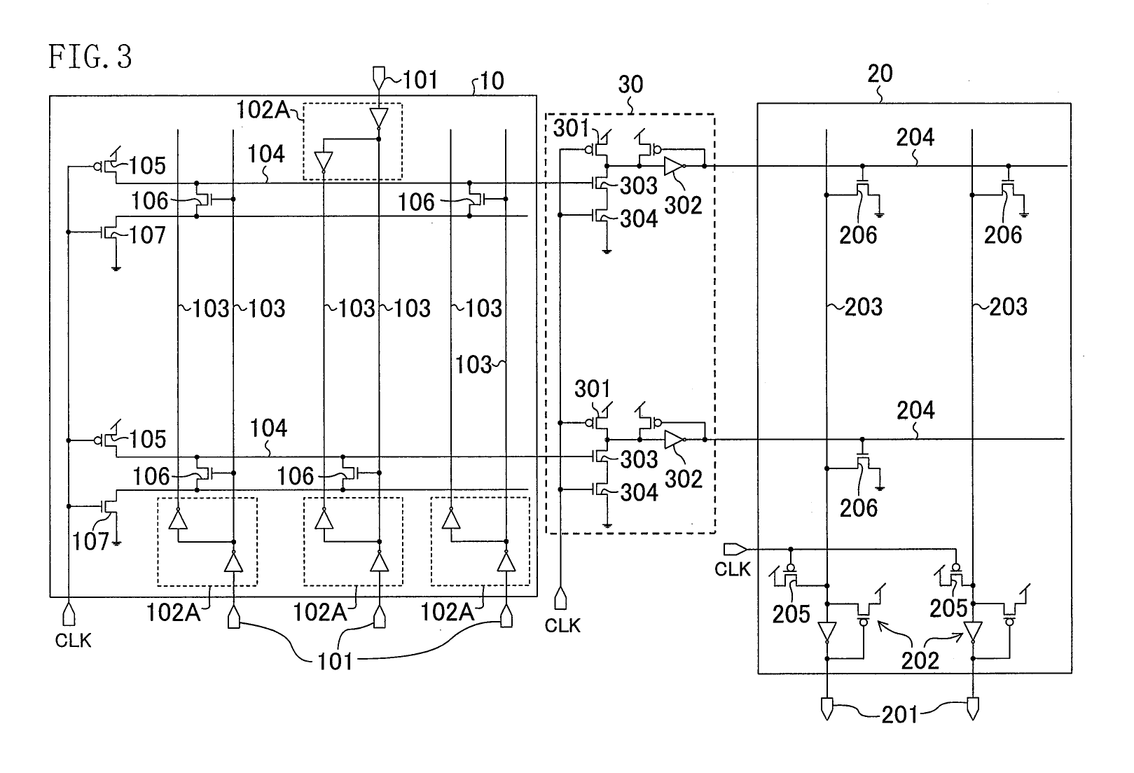

FIG. 3 shows the configuration of a PLA according to Embodiment 3 of the invention. In the PLA of this embodiment, the input buffer 102 of the PLA of FIG. 1 is replaced with a buffer circuit 102A and the data line 103 is constructed as a line pair. The rest of the configuration is the same as that of Embodiment 1 and hence the description is omitted.

The buffer circuit 102A generates inverted and non-inverted signals of one signal input to the input terminal 101 and supplies a differential signal to a pair of adjacent data lines 103. Thus, the directions of lines of magnetic force generated from adjacent input buffers (that is, the inverters in this embodiment) in signal propagation are made reverse to each other, so as to reduce spurious radiation.

### Embodiment 4

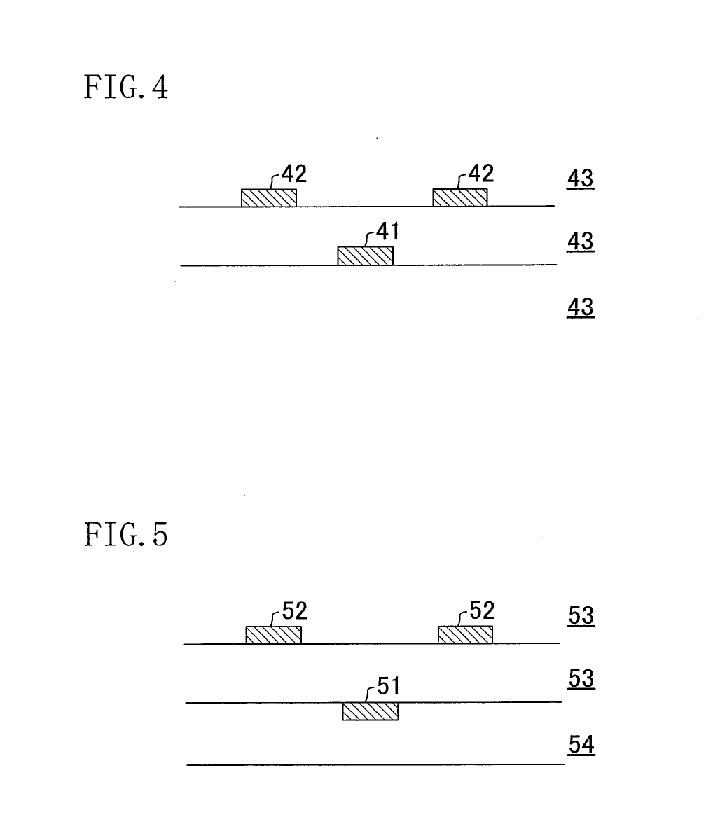

FIG. 4 is a cross-sectional view of data lines of a PLA according to Embodiment 4 of the invention. In FIG. 4, a reference numeral 41 denotes an interconnection of an N-layer, a reference numeral 42 denotes an interconnection of an N+1-layer and a reference numeral 43 denotes an interlayer insulating film. At this point, N is a natural number, and the N-layer and the N+1-layer are both metal interconnection layers. Each metal interconnection layer is surrounded with the interlayer insulating film 43. The data lines may be provided an input plane or an output plane.

In this embodiment, since the adjacent data lines are formed in the different layers in the vertical direction, capacitance caused between the interconnections is reduced and the superimposition of lines of magnetic force generated from the interconnections is reduced.

### Embodiment 5

FIG. 5 is a cross-sectional view of data lines of a PLA according to Embodiment 5 of the invention. In FIG. 5, a reference numeral 51 denotes a diffusion layer interconnection, a reference numeral 52 denotes a metal interconnection, a reference numeral 53 denotes an interlayer insulating film and a reference numeral 54 denotes a silicon substrate. The data lines may be provided in an input plane or an output plane.

In this embodiment, since adjacent signal lines are formed in different layers in the vertical direction and formed in a diffusion layer, the capacitance caused between the interconnections is reduced, and moreover, since the interconnection resistances are different, there arises a difference in time for propagation to an output buffer, and therefore, the superimposition of lines of magnetic force generated from adjacent output buffers can be suppressed.

### Embodiment 6

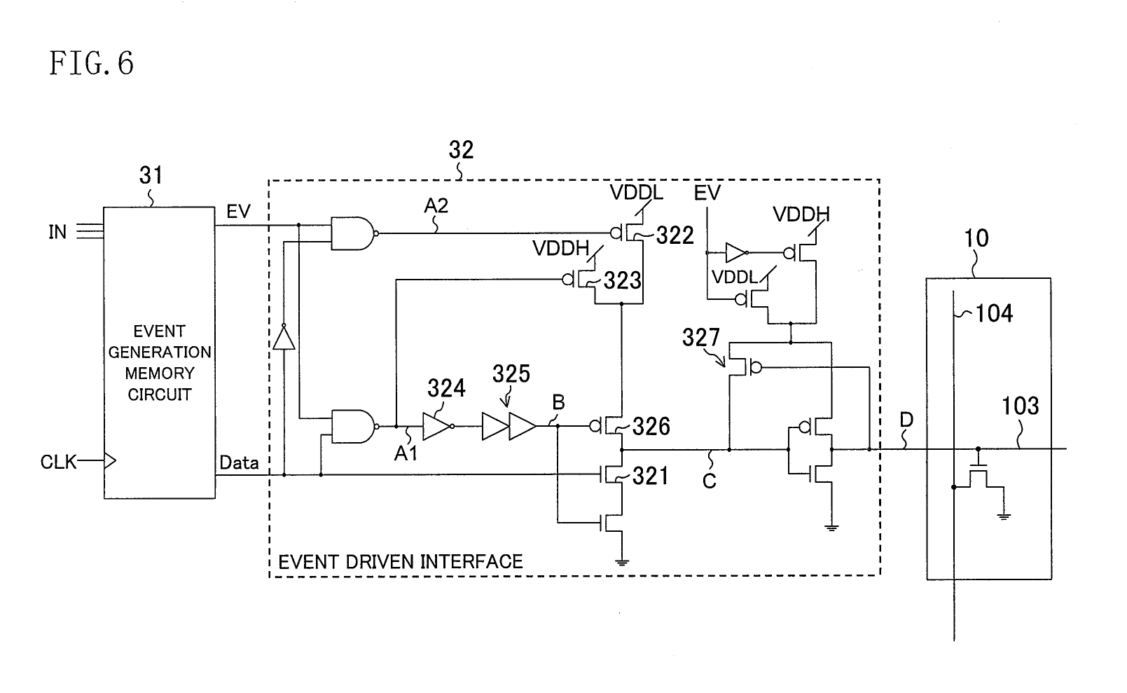

FIG. 6 shows the configuration of an event driven interface portion of a PLA according to Embodiment 6 of the invention. The PLA of this embodiment includes an event generation memory circuit 31 and an event driven interface 32 in a signal input portion of an input plane 10.

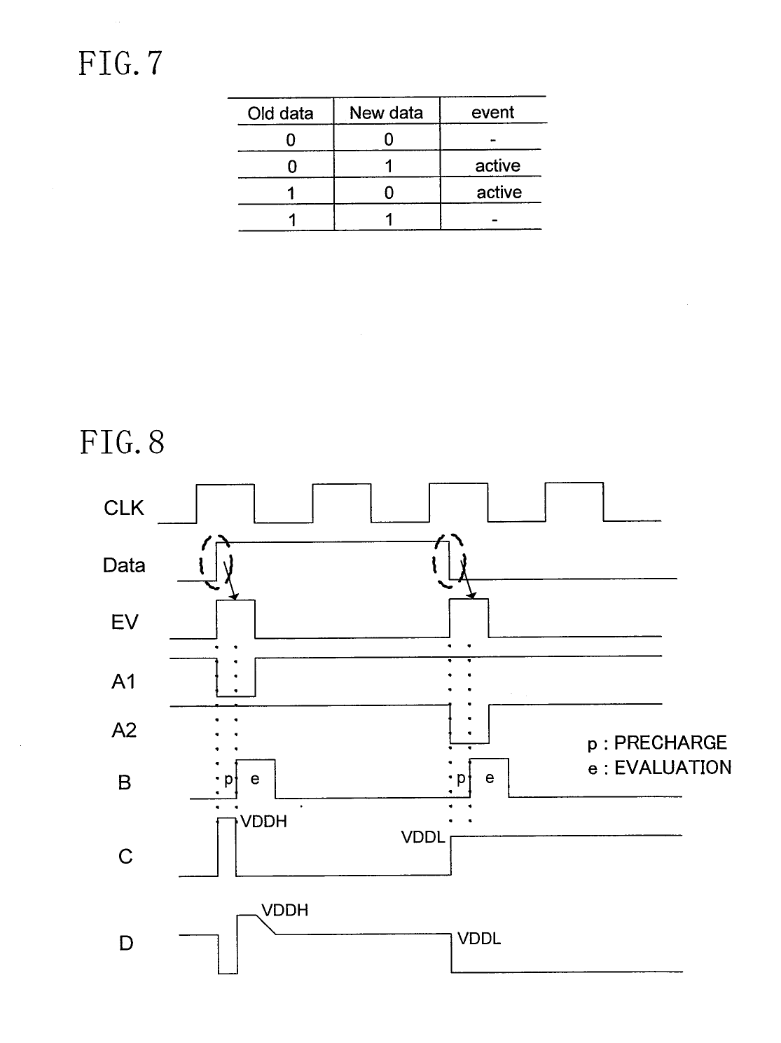

The event generation memory circuit 31 stores, as shown in a truth table of FIG. 7, a transition state attained in accordance with a given signal IN, and generates an event EV in synchronization with a clock CLK when the stored content is changed. It is noted that the event driven circuit is specifically disclosed in, for example, Japanese Patent Application No. 2004-229842.

The event driven interface 32 evaluates, when the event EV supplied from the event generation memory circuit 31 is activated, the stored content of the event generation memory circuit 31 and supplies the result of the evaluation to a data line 103 of the input plane 10. Also, the event driven interface 32 can select any of a plurality of power voltages in accordance with the event EV.

The operation of the event driven interface 32 will now be described with reference to a timing chart of FIG. 8. In accordance with transition edges of the signal CLK and a signal Data, the event EV is activated (to become high). At this point, when the signal Data is changed to rise, a node A1 is activated (to become low) and a power voltage VDDH is connected. On the other hand, when the signal Data is changed to fall, a node A2 is activated (to become low) and a power voltage VDDL is connected. It is herein assumed that there is a relationship of VDDH>VDDL.

The precharge is performed during a period from a fall edge of an inverted signal of the event EV to a rise edge of a signal obtained by delaying the event EV, and the evaluation is performed during a Hi level period of the delayed signal of the event EV. Herein, since the event driven interface 32 is constructed based on the dynamic logic, in the case where the output signal Data of the event generation memory circuit 31 undergoes a Lo to Hi transition, an Nch transistor 321 working as an evaluation transistor is turned on so as to propagate the logic to subsequent stages.

During this operation, the power voltage VDDH, that is, a higher one of the two kinds of power voltages, is connected merely in the precharge, and the power voltage is switched to the lower power voltage VDDL in and after the evaluation period. On the contrary, in the case where the signal Data undergoes a Hi to Lo transition, a logic kept in a precharged state is propagated. During this operation, the precharge level is recognized, and the power voltage is set to the power voltage VDDL lower than a threshold voltage at which a subsequent inverter is not inverted.

Referred to FIG. 6 again, the circuit configuration of the event driven interface 32 will be described. In the event driven interface 32, the event EV and an inverted signal of the signal Data are NAND connected to each other so as to supply the resultant signal to the gate of a Pch transistor 322 working as a voltage supply circuit and receiving the lower power voltage VDDL at its source. On the other hand, the event EV and the signal Data are NAND connected to each other so as to supply the resultant signal to the gate of a Pch transistor 323 working as a voltage supply circuit and receiving the higher power voltage VDDH at its source. Thus, the power voltage to be used in the precharge is selected in accordance with the direction of the level transition of the signal Data. Also, a precharge pulse is generated by a Pch transistor 326 that works as a precharge circuit for receiving a signal obtained by inverting, by an inverter 324, a NAND of the event EV and the signal Data and by delaying the inverted signal by a buffer circuit 325. Moreover, the voltages VDDH and VDDL are selectively supplied in accordance with the event EV as the power voltage for a keeper circuit 327 used for preventing error data inversion of a dynamic node.

As described above, according to this embodiment, the activation yield of the circuit is lowered by the event driven interface, and furthermore, since the two kinds of power voltages are selectively used as the source power and the event driven interface used for pulse precharge is included as an interface buffer of the PLA, a steady state current is reduced. Assuming that, for example, VDDH=1.2 V and VDDL=0.9 V, since the power P=f·C·V², the power is reduced by approximately 40% when f and C are constant.

It is noted that the event driven interface may be provided previous to the output plane instead of the interface buffer 30 shown in FIG. 1.

### Embodiment 7

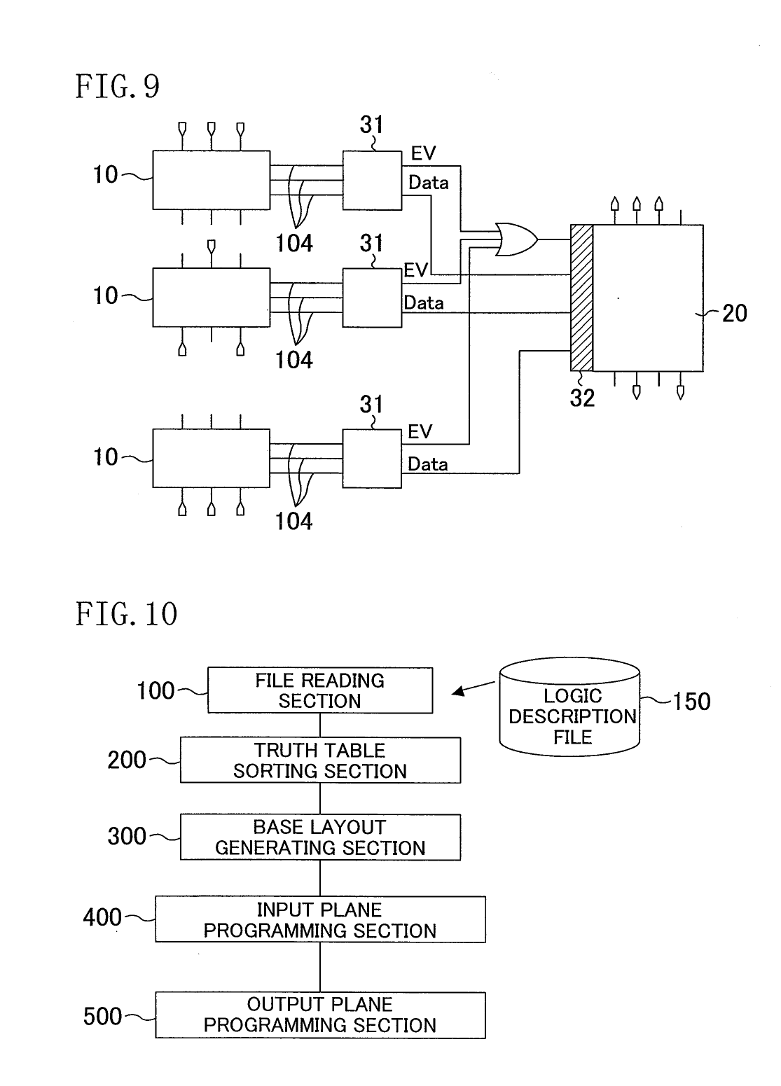

FIG. 9 shows the configuration of a PLA according to Embodiment 7 of the invention. In the PLA of this embodiment, an event driven interface 32 is operated on the basis of events EV generated from a plurality of event generation memory circuits 31.

The event generation memory circuit 31 corresponding to each of a plurality of input planes 10 receives signals supplied through product term lines 104 of the corresponding input plane 10 and generates an event EV when any of the signals is changed. The events EV generated from the respective event generation memory circuits 31 are ORed to be supplied to the event driven interface 32. The event driven interface 32 is supplied with a signal Data corresponding to a stored content of each event generation memory circuit 31.

In this manner, according to the present embodiment, the input plane 10 is plurally divided so as to selectively supply power voltages in transition of an input signal in accordance with the direction of the transition, and therefore, an unnecessary steady state current can be effectively reduced and portions where spurious radiation occurs can be reduced.

### Embodiment of PLA Module Generator

FIG. 10 shows the architecture of a PLA module generator according to the present invention. The PLA module generator of this invention includes a file reading section 100, a truth table sorting section 200, a base layout generating section 300, an input plane programming section 400 and an output plane programming section 500.

The operation of the PLA module generator of this embodiment is as follows: First, the file reading section 100 reads a logic description file 150 described on the basis of a truth table. The truth table sorting section 200 sorts the read truth table. This will be described in detail later. The base layout generating section 300 generates a base layout on the basis of the read logic description film 150. Furthermore, the input plane programming section 400 positions array transistors in an input plane on the basis of the logic description film 150. Subsequently, the output plane programming section 500 positions array transistors in an output plane. A PLA is generated through this process flow.

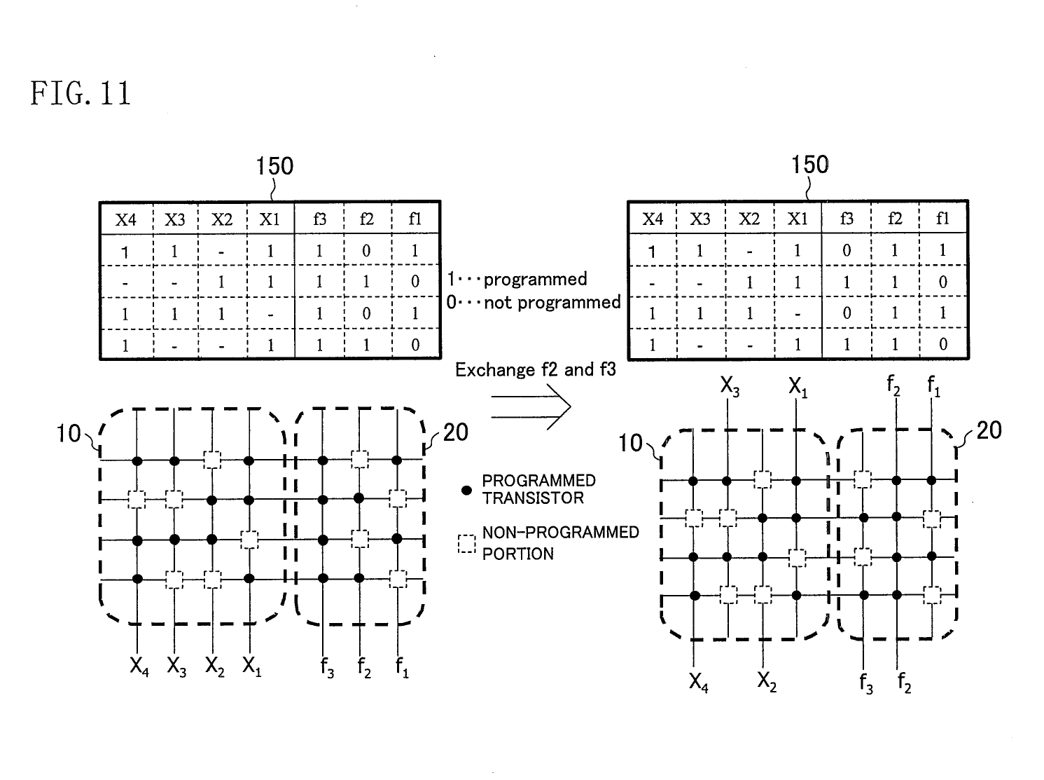

Next, the outline of the truth table sorting performed by the truth table sorting section 200 will be described with reference to FIG. 11. The left half of FIG. 11 shows a truth table obtained before the sorting and the plane configuration of the PLA obtained based on the truth table. The right half of FIG. 11 shows a truth table obtained after the sorting and the plane configuration of the PLA actually laid out.

First, configuration ratios of programmed transistors and non-programmed portions are detected in each column of the truth table 150 obtained before logical exchange (namely, the left half of FIG. 11), and the columns are exchanged so that a column with a large ratio of the programmed portion and a column with a small ratio of the programmed portion can be paired to be adjacent to each other. In the example shown in FIG. 11, data lines f2 and f3 of an output plane 20 are exchanged, resulting in obtaining the truth table 150 shown in the right half of FIG. 11.

In this manner, according to the PLA module generator of this embodiment, columns are exchanged so that a column with a high ratio of a programmed portion and a column with a low ratio of the programmed portion can be adjacent to each other, and therefore, the probability that adjacent columns are simultaneously switched is lowered even slightly, and change in currents to the same direction caused in adjacent columns is reduced. In other words, the superimposition of lines of magnetic force is reduced, so as to prevent increase of the spurious radiation. Furthermore, since the truth table sorting section 200 is provided in the module generator, process return for re-positioning after layout design can be avoided.

### INDUSTRIAL APPLICABILITY

Since a programmable logic array and a programmable logic array module generator of this invention have a high speed property and a low EMI characteristic (a low power consumption characteristic), they are useful for a control circuit or the like of a microprocessor of a high clock frequency.

1. A programmable logic array comprising:
an input plane including a plurality of data lines and a plurality of product term lines having voltage levels changed in accordance with signal input to the plurality of data lines; and
an output plane including a plurality of product term lines having voltage levels changed in accordance with change of the voltage levels of the plurality of product term lines of the input plane and a plurality of data lines for outputting signals in accordance with the voltage levels of the plurality of product term lines,
at least one of the plurality of data lines of at least one of the input plane and the output plane having data terminals at both ends thereof.

2. The programmable logic array of claim 1,
wherein the input plane includes a precharge circuit for precharging the plurality of product term lines of the input plane, and
the precharge circuit is provided at a center along a length direction of the plurality of product term lines.

3. The programmable logic array of claim 1,
wherein the output plane includes a precharge circuit for precharging the plurality of data lines of the output plane, and
the precharge circuit is provided at a center along a length direction of the plurality of data lines.

4. The programmable logic array of claim 1,
wherein the input plane includes, for at least one data line out of the plurality of data lines of the input plane, a buffer circuit for generating an inverted signal and a non-inverted signal of a signal input to the one data line, and
the one data line is a line pair for transferring the generated inverted and non-inverted signals.

5. The programmable logic array of claim 1,
wherein adjacent data lines of the plurality of data lines of at least one of the input plane and the output plane are provided in different interconnection layers.

6. The programmable logic array of claim 5,
wherein at least one of the plurality of data lines is a diffusion layer interconnection.

7. The programmable logic array of claim 1, further comprising:
an event generation memory circuit for storing a transition state obtained in accordance with a supplied signal, and generating an event when a stored content is changed; and
an event driven interface for evaluating the stored content of the event generation memory circuit to output an evaluation result when an event is received from the event generation memory circuit,
wherein the event generation memory circuit receives a signal input to the input plane, and
the event driven interface supplies the evaluation result to the plurality of data lines of the input plane.

8. The programmable logic array of claim 1, further comprising:
an event generation memory circuit for storing a transition state obtained in accordance with a supplied signal, and generating an event when a stored content is changed; and
an event driven interface for evaluating the stored content of the event generation memory circuit to output an evaluation result when an event is received from the event generation memory circuit,
wherein the event generation memory circuit receives signals output from the plurality of product term lines of the input plane, and
the event driven interface supplies the evaluation result to the plurality of product term lines of the output plane.

9. The programmable logic array of claim 8,
wherein each of the input plane and the event generation memory circuit is plural in number,
each of the plural event generation memory circuits receives the signals output from the plurality of product term lines of each of the plural input planes, and
the event driven interface evaluates stored contents of the plural event generation memory circuits to supply evaluation results to the plurality of product term lines of the output plane when an event is received from any of the plural event generation memory circuits.

10. The programmable logic array of claim 7,
wherein the event driven interface includes:
a precharge circuit for precharging a given node of the event driven interface with a supplied voltage on the basis of a signal obtained by delaying the event;
a first voltage supply circuit for supplying a first voltage to the precharge circuit when an event generated in transition of the stored content of the event generation memory circuit from a first value to a second value is in an active state; and
a second voltage supply circuit for supplying a second voltage lower than the first voltage to the precharge circuit when an event generated in transition of the stored content of the event generation memory circuit from the second value to the first value is in an active state.

11. The programmable logic array of claim 1,
wherein a MOS device included in the programmable logic array is formed on a SOI wafer.

12. A programmable logic array module generator comprising:
a file reading section for reading a logic description file related to a programmable logic array;
a truth table sorting section for exchanging a plurality of data lines of at least one of an input plane and an output plane of the programmable logic array described by the logic description file in such a manner that a data line including a relatively large number of transistors is adjacent to a data line including a relatively small number of transistors;
a base layout generating section for generating a base layout on the basis of a logic description file obtained by exchanging the data lines;
an input plane programming section for positioning an array in the input plane on the basis of the logic description file obtained by exchanging the data lines; and
an output plane programming section for positioning an array in the output plane on the basis of the logic description file obtained by exchanging the data lines.

13. The programmable logic array of claim 8,
wherein the event driven interface includes:
a precharge circuit for precharging a given node of the event driven interface with a supplied voltage on the basis of a signal obtained by delaying the event;
a first voltage supply circuit for supplying a first voltage to the precharge circuit when an event generated in transition of the stored content of the event generation memory circuit from a first value to a second value is in an active state; and
a second voltage supply circuit for supplying a second voltage lower than the first voltage to the precharge circuit when an event generated in transition of the stored content of the event generation memory circuit from the second value to the first value is in an active state.
